(19) United States
(12) Patent Application Publication
(10) Pub. No.: US 2005/0109280 A1
(43) Pub. Date: May 26, 2005

(54) Rapid thermal chemical vapor deposition apparatus and method

(76) Inventors: Xiangqun S. Chen, Valencia, CA (US); Dennis M. Adderton, Santa Barbara, CA (US)

Correspondence Address: BOYLE FREDRICKSON NEWHOLM STEIN & GRATZ, S.C., 250 E. WISCONSIN AVENUE, SUITE 1030, MILWAUKEE, WI, 53202, US

(21) Appl. No.: 10/945,814

(22) Filed: Sep. 21, 2004

Related U.S. Application Data
(60) Provisional application No. 60/505,360, filed on Sep. 22, 2003.

(51) Int. Cl. C23C 16/00

(52) U.S. Cl. 118/724

(57) ABSTRACT

A carbon nanotube fabricating system and method that includes a process chamber that supports a substrate. The system employs a high intensity thermal radiation source for heating the chamber, and a temperature regulation chuck that supports the substrate. In process, the chuck cools the substrate so as to prevent damage to the substrate, while CNT fabrication is preferably regulated to occur in a process window.

### CROSS REFERENCE TO RELATED APPLICATION

This application is a non-provisional application based on a provisional application Ser. No. 60/505,360 filed on Sep. 22, 2003, the entirety of which is expressly incorporated by reference herein.

### BACKGROUND OF THE INVENTION

1. Field of the Invention

The present invention is directed to a chemical vapor deposition (CVD) system and corresponding method, and more particularly, a CVD system and method for carbon nanotube synthesis on a substrate using an apparatus employing a rapid thermal process.

2. Description of Related Art

Since their discovery over a decade ago, carbon nanotubes have shown great promise in a wide variety of technologies, including extending Moore's Law beyond the physical limitations of known silicon techniques. Carbon nanotubes are much like elongated bucky balls, a form of carbon-composed clusters of approximately 60 carbon atoms, bonded together in an apolyhedral, or many-cited structure composed of pentagons and hexagons, like the surface of a soccer ball. Shaped-like cylinders of chicken wire, nanotubes may comprise single-walled or concentric multi-walled tubes that range, for example, between 0.4 and 20 nanometers thick. Generally, single-walled carbon nanotubes are preferred over multi-walled carbon nanotubes for use in the applications contemplated by the present invention because they have fewer defects and are therefore stronger and more conductive than multi-walled carbon nanotubes of similar diameter.

Notably, nanotubes can be at least a 100 to 1000 times stronger than the strongest steel and have excellent electron-emission capabilities. What makes such structures even more appealing is their durability. When used as probe tips for atomic force microscopy, attempts to “crash” or damage the tubes have proved difficult due to the inherent flexibility that allows them to return to their original shape. Overall, the unique properties of nanotubes make them suitable for nanometer scale wires, transistors, quantum devices and sensors. Moreover, carbon nanotubes can be engineered to act as metallic conductors, semi-conductors, insulators or diode junctions, for example, and modeling predicts that they may also be made to exhibit super conductivity and magnetism.

One challenge in the field of producing carbon nanotubes is been how to exploit the structures for use in the desired applications, such as in field emission devices. On the microscopic level, nanotubes have typically been made by processes resulting in tubes that are inconveniently integrated in a twisted clump. For example, nanotubes have been produced by vaporizing carbon with an electric current. In this case, the vapor condenses to form a sooty clump, rich in nanotubes. One wanting to extract such nanotubes, however, has to then painstakingly tease out individual tubes for use in their experimental research. For example, in the manufacture of carbon nanotube atomic force microscopy probes, workers typically will mine the clump with, for example, cellophane tape, and then lightly touch a glue-dipped conventional tip to the wad of nanotube bundles and gingerly pluck each tube out. This type of bulk production and extraction of nanotubes is generally unworkable, especially for any application anticipating large scale production. As a result, techniques have since been developed to precisely pattern the carbon nanotubes on a substrate according to a user's particular requirements. In this case, such “teasing” of the tubes is eliminated.

For instance, elongated bucky balls, or nanotubes, are now being grown on a substrate in a well-aligned manner, resembling a wheat field. More specifically, nanotubes are often grown on a substrate by catalytic decomposition of hydrocarbon-containing precursors such as ethylene, methane or benzene. In this fashion, nanotubes can be made in the form of a collection of free-standing nanoconnectors substantially equal in length. In one application, carbon nanotubes are patterned into individual field emitters to provide an array of emitters which may be used in applications such as flat panel displays.

In general, catalyzed chemical vapor deposition (CVD) has been employed for the growth of carbon nanotubes in a process that is both scalable and compatible with integrated circuit and MEMS manufacturing processes. Notably, CVD allows high specificity of single wall or multi-wall nanotubes through appropriate selection of process gases and temperature. The carbon feed stock is generated by the decomposition of a feed gas such as methane or ethylene. The associated high stability of the feed gas prevents it from decomposing in the elevated temperatures of the nanotube fabrication furnace, which is typically 700 to 1000 degrees Celsius.

Preferably, decomposition of the feed gas occurs only at the catalyst sites, thus reducing amorphous carbon generated in the process. Decomposed carbon molecules then assemble into nanotubes at the catalyst nano-particle sites. Advantageously, catalyst nano-particles can be patterned on a substrate lithographically to realize nanotube growth at intentional locations, as suggested previously. For example, the growth of nanotubes can be caused to originate at a site of electrical connections or of mechanical significance.

Overall, carbon nanotubes have been demonstrated as enabling components for various electronic and chemical-mechanical devices functional on the molecular scale. Notably, in addition to enabling nano-scale electronic devices, nanotubes are proving to be useful for chemical and biological sensing. Semi-conducting carbon nanotubes have been used at Stanford University to detect gas molecules, and semi-conductor nanowires have been used as ultra sensitive detectors for a wide range of biological compounds. Such devices include chemical for sensors, gas detectors, field emission displays, molecular wires, diodes, FET's, and single-electron transistors.

In one highly significant application, synthesizing carbon nanotubes on a substrate made of a display glass for making flat panel field emission displays for televisions, for example, has been attempted. Classically, carbon emitting devices have been disposed on a glass substrate. Two primary methods for disposing carbon nanotubes that can operate as field-emitting devices on a glass substrate have been laser ablation and what is known as arc discharge. The way in which this has been done is using one of two methods known as thermal CVD and Plasma Enhanced CVD (PECVD), both of which can provide direct synthesis of nanotubes on substrates. In thermal CVD, the process temperature range may be from 550° C. to 1,000° C. One problem with such a system is that these high temperatures can compromise the substrate. With a glass substrate, for example, the glass will likely be unable to endure the heat and thus experience a phase transition. This greatly inhibits the use of thermal CVD to produce carbon nanotubes directly on a substrate for such applications.

Nevertheless, such high temperatures are required for the carbon molecules to bond into nanotubes. Even with the catalyst to help the bonding, you still need a significant amount of energy to bond the carbon molecules together. The synthesis of carbon nanotubes is shown according to two known phenomena where bottom growth and top growth, respectively, are shown in FIGS. 1 and 2.

More particularly, a catalyst may be provided in different forms, such as in a solution or it can be patterned by direct deposition on a support structure such as a substrate 20, as noted previously. Typically, iron, nickel, cobalt, or an alloy of these metals could be used for the catalyst. What results is the formation of catalyst nano-particles 22 and 22′ having a particular diameter “d” of these metals on the substrate 20 that provide catalyst sites. Once the pattern is created, an environment having an elevated temperature is created and then carbon stock is introduced. Notably, the lowest known temperature for thermal CVD is about 540°, as accepted in the art.

Typically, the carbon stock may be provided by a gas such as methane. These gases that flow near the vicinity of the sidewalls of the catalysts of the particles start a chemical reaction yielding carbon hydrate or carbon monoxide. Often, this process is referred to as infusing carbon into the particle. The carbon molecules saturate the metal and it crystallizes and starts to synthesize into a nanotube. Again, the catalysts are in the form of a nanoparticle. During process, a nanometer-sized sphere of catalyst wants to crystallize into a graphitic sheet. The hexagonal sheets of carbon have layers with weak bonds between the layers but the hexagonal sheets themselves are covalent. Because of the dimensional constraint, it wants to close the tube because otherwise, at the end of the sheet, you have dangling bonds. If you constrain the size to a few nanometers, it will close into a tube.

After saturation, the tubes start to crystallize on the surface of the catalyst particle and the nanotube is synthesized and grown into a tube. For bottom growth shown in FIG. 1, the tube 24 synthesizes on top of nano-particle 22, with the nano-particle being generally fixed to substrate 20. In FIG. 2, nano-particle 22′ remains on top of Tube 24′ while the tube synthesizes beneath according to conditions understood in the art of synthesizing carbon nanotubes.

In this case, the size of the catalyst sites correspond to the size of the nanotube most often. More particularly, the diameter of the catalyst generally corresponds to the diameter of the nanotube. Because small diameters are required for many applications, smaller catalyst sites are preferred.

Overall, the quality of tubes is determined by, among other things, the defects associated therewith, which affect conductivity and, for the application of field emission displays, the overall quality of the emission of the tube. In general, the quality affects the overall electrical properties of the tube. Moreover, length of the tube, as well as diameter, are often important characteristics in determining the usefulness of the tube, which is especially the case for the field emission display application discussed herein.

For example, when synthesizing nanotubes for the field emission display application discussed previously, the emission characteristics of the corresponding nanotube are defined by a number of factors. Importantly, there is a field concentration factor associated with the nanotube. In this example, as shown in FIG. 3, a voltage is applied between the substrate 10 on which the nanotube 30 is supported and an opposed plate 34 to cause the nanotube to emit a field at its tip 32. Often, the greater the field emission concentration, the greater the performance for display applications, as understood in the art. Notably, the field is proportional to a constant times a quantity equal to the voltage divided by the distance “d” shown in FIG. 3. Moreover, the emission field intensity is proportional to one over the effective radius, R, at the tip 32 of nanotube 30. Clearly, the smaller the radius, i.e., the sharper the tip 32, the greater the field concentration factor, and thus the greater performance. As a result, and in view of the above discussion, the size of the nanoparticle in terms of diameter as shown in FIGS. 1 and 2, is critical to the performance in such applications. Again, the smaller the diameter of the nanoparticle, the more narrow the nanotube and thus the greater field emission concentration.

Thermal CVD produces high quality carbon nanotubes because the relatively high temperatures (as opposed to PECVD, for example) allow smaller nanoparticles to be used as catalyst sites thus producing high aspect ratio tubes having a narrow diameter and being generally defect free in terms of being defined by a single crystal with uninterrupted layers. However, high quality, long nanotubes often come at the expense of compromising the substrate and/or other structure thereon (e.g., electronic components) due to adverse thermal effects. Moreover, in thermal CVD, high temperature corresponds to higher costs for mass production, primarily due to energy consumption.

These factors are linked to thermal budget(s) in the system which may be compromised. Again, when doing direct synthesis of carbon nanotubes, there may be other structure/components on the substrate that must be protected. These components typically have a thermal budget associated therewith that must not be exceeded, otherwise the components may be damaged. When considering thermal CVD, the overall thermal budget for the device, and application in general, is often critical.

On the other hand, one problem with Plasma Enhanced CVD (PECVD) is that it is very difficult to get the proper combination of small catalyst sites and high quality nanotubes. In PECVD, additional energy is provided to the system (i.e., to the carbon molecules) by providing a plasma at the substrate surface. This plasma energy facilitates nanotube synthesis without using additional heat energy, as in thermal CVD. Nevertheless, as a result of using lower temperatures, the alignment of the nanotubes when directly synthesized on a substrate may not be ideal when performing PECVD. Moreover, such tubes, especially when using small catalyst sites (as preferred) exhibit defects upon examination, where the tubes do not comprise a single crystal, i.e., the tube has interrupted layers. This most often will significantly affect the electrical properties, (such as field emission properties) of the nanotubes for such applications, as discussed in connection with FIG. 3. Overall, because the carbon nanotubes are synthesized at lower temperatures, the integrity of the substrate can be maintained, but typically only at the expense of useful nanotubes for at least some applications.

The art of producing carbon nanotubes was thus in need of a system and/or method capable of producing high quality carbon nanotubes on a wide range of substrates while preserving thermal budgets associated with the application.

### SUMMARY OF THE INVENTION

The preferred embodiment is directed to a rapid thermal CVD carbon nanotube synthesis system and method that employs rapid infrared heating and precise thermal control to produce carbon nanotubes directly on a substrate for a variety of applications, while maintaining the integrity of the substrate and any structure associated therewith. More particularly, in one preferred embodiment, the system employs infrared heating and precise thermal control to synthesize carbon nanotubes directly on a substrate uniformly by controlling temperature rapidly and in a non-isothermal fashion based on application parameters including nanotube characteristics, thermal budgets, etc. Also, this goal can be further achieved by controlling gas flow and gas distribution in a non-uniform fashion, with or without the aforementioned temperature control.

According to a first aspect of the preferred embodiment, a carbon nanotube fabrication system including a chamber that supports a substrate includes the substrate, and a layer on top of the substrate, the layer having upper and lower generally opposed surfaces and at least one catalyst site for growing a carbon nanotube. The system also includes a high intensity thermal radiation source for heating the chamber, wherein an increase in temperature at the substrate lags a temperature increase at the catalyst site.

According to a another aspect of the preferred embodiment, a temperature regulation chuck supports the substrate. In this case, the chuck cools the substrate so as to prevent damage thereto.

In yet another aspect of the preferred embodiment, CNT growth is regulated to occur in a process window substantially defined by a point at which a target temperature for CNT synthesis substantially occurs and a point at which a glass transition temperature of the substrate substantially occurs.

According to a further aspect of the preferred embodiment, a CNT synthesis temperature is achieved from an ambient temperature in less than about 1 minute, and even more preferably, the CNT synthesis temperature is achieved from an ambient temperature in less than about 30 seconds.

According to a still further aspect of the preferred embodiment, a method of producing carbon nanotubes on a substrate includes the steps of heating a chamber to a CNT synthesis temperature faster than heating the chamber to the CNT synthesis temperature in thermal CVD. Next, the process includes synthesizing the carbon nanotubes in a process window defined by a difference in time between a point at which the CNT temperature is substantially achieved and a point, t_{cool}, at which the temperature at a top surface of the substrate substantially achieves a glass transition temperature.

In a further aspect of the preferred embodiment, the method further includes the step of cooling the substrate starting at time t_{cool}. In this case, the cooling step preferably includes using a temperature regulated chuck that supports the substrate.

According to a further aspect of this embodiment, a layer is supported by the substrate, the layer having upper and lower generally opposed surfaces separated by a thickness. In addition, the upper surface includes a plurality of catalyst sites and at least one component having a thermal budget. In this case, the heating step is performed so as to generally not exceed the thermal budget.

According to a yet another aspect of the preferred embodiment, a carbon nanotube fabrication system having a chamber that supports a substrate includes a high intensity thermal radiation source for heating the chamber, and a temperature regulation chuck that supports the substrate. In this embodiment, the chuck cools the substrate so as to prevent damage to the substrate during formation of the carbon nanotubes.

These and other objects, features, and advantages of the invention will become apparent to those skilled in the art from the following detailed description and the accompanying drawings. It should be understood, however, that the detailed description and specific examples, while indicating preferred embodiments of the present invention, are given by way of illustration and not of limitation. Many changes and modifications may be made within the scope of the present invention without departing from the spirit thereof, and the invention includes all such modifications.

### BRIEF DESCRIPTION OF THE DRAWINGS

A preferred exemplary embodiment of the invention is illustrated in the accompanying drawings in which like reference numerals represent like parts throughout, and in which:

FIG. 1 is a schematic front elevational view of a carbon nanotube being synthesized, illustrating bottom growth;

FIG. 2 is a schematic front elevational view of a carbon nanotube being synthesized, illustrating top growth;

FIG. 3 is a schematic front elevational view of a carbon nanotube having field emission properties;

FIG. 4 is a schematic front elevational view of a rapid thermal chemical vapor deposition system according to a preferred embodiment;

FIG. 5 is a schematic perspective view of the system shown in FIG. 4:

FIG. 6 is a partially broken away schematic elevational view of a substrate having electronic devices and catalyst sites for nanotube synthesis;

FIG. 7 is a graph illustrating thermal characteristics during nanotube synthesis;

FIG. 8 is a schematic cross-sectional perspective view of a portion of the apparatus shown in FIG. 4;

FIG. 9 is a schematic front elevation cross-sectional view of the apparatus shown in FIG. 8;

FIG. 10 is a flow chart illustrating a rapid thermal CVD process according to a preferred embodiment;

FIG. 11 is a flow chart illustrating a process according to an alternate preferred embodiment; and

FIG. 12 is a schematic perspective view of a rapid thermal chemical vapor deposition system according to an alternative embodiment

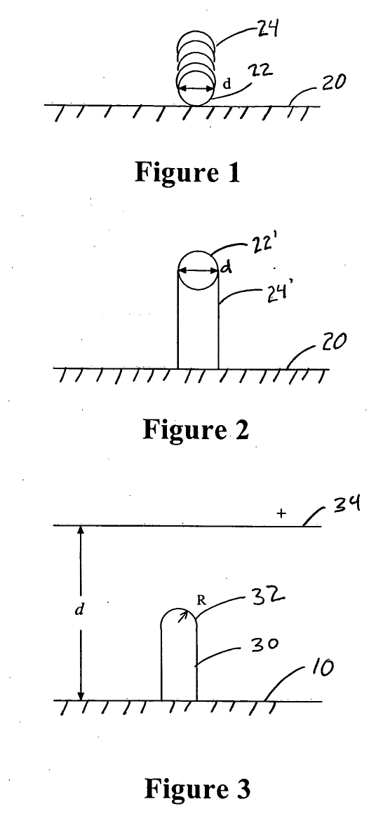

### DETAILED DESCRIPTION OF THE PREFERRED EMBODIMENT

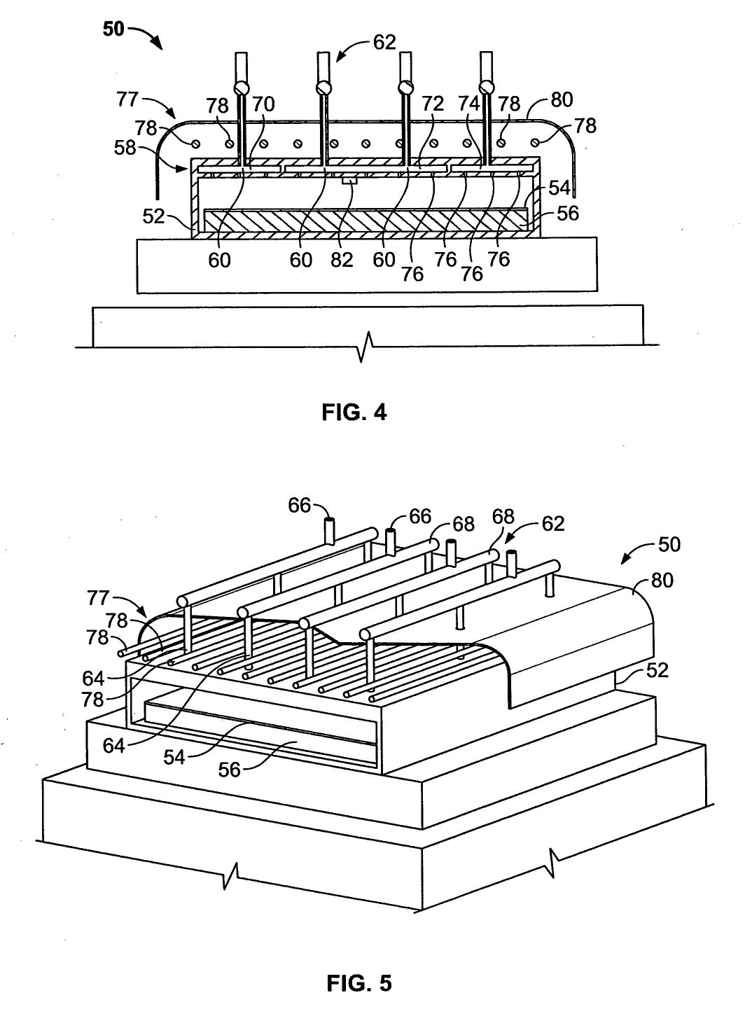

Turning initially to FIGS. 4 and 5, a rapid thermal CVD carbon nanotube fabrication apparatus 50 includes a chamber 52, preferably made of quartz, having a rectangular cross-section designed to accommodate a substrate 54, for example a flat, rectangular glass substrate for a field emission display application. The dimensions of chamber 52 are not intended to limit the scope of the preferred embodiment, they are only schematically illustrated for purposes of example only. Substrate 54 is supported by a temperature regulated chuck 56, the function of which will be apparent from the discussion below.

The quartz chamber 52 preferably includes a multi-zone showerhead 58 that includes a plurality of openings 60 coupled to a gas delivery system 62 for receiving gas from any number of gas sources (not shown). More specifically, gas delivery system 62 includes a plurality of pipes 64, 66, 68 coupled to chamber 52, and specifically, showerhead 58.

Showerhead 58 preferably includes inlets 60 for receiving one or more gasses in a plurality of zones, the number of which being selected according to the application. The showerhead, in this case, includes three zones 70, 72, 74 for mixing gasses to allow uniform distribution of gasses into the chamber upon execution of a carbon nanotube growth recipe. Uniform synthesis of nanotubes on a substrate 54 is critical in many applications and thus more discussion regarding how gas delivery affects this uniformity is provided below. Notably, gasses are communicated to the interior of chamber 52 via a plurality of outlets 76 extending from the zones of showerhead 58.

Next, system 50 includes a heat source 77 including an array of high energy density light sources 78, preferably halogen bulbs that generate infrared heat, that direct the corresponding heat toward chamber 52 and thus substrate 54. Sources 78 preferably extend beyond the length of chamber 52 to insure uniformity. Spacing and distance of sources 78 from chamber 54 are selected to maximize the ability to heat the substrate as fast as possible. Moreover, to maximize the heat coupled through chamber 52 and towards substrate 54 (important for rapid heating, discussed below), a reflector 80 is employed to insure efficient transmission of the heat energy.

The heat source 77, which preferably includes sources 78 and reflector 80, and temperature regulated chuck 56 operate collectively to maintain optimum temperature conditions for synthesizing high quality carbon nanotubes on substrate 54 without compromising the integrity of substrate 54 and insuring conditions do not exceed the thermal budgets associated with the application. To measure the temperature of the synthesis, a sensor 82, such as a pyrometer, is preferably placed within chamber 54, and more preferably at the top inside wall thereof. Because rapid heating of substrate 54 is important, sensor 82 most be of sufficient quality (appropriate time constant, etc.) to provide accurate feedback regarding temperature conditions associated with the CNT (carbon nanotube) synthesis. If temperature needs to be adjusted, the system must be able to follow the temperature profile discussed below or else nanotube quality or substrate integrity may be compromised.

Temperature regulated chuck 56 can be any structure known in the art such as a slab including cooling channels that provide backside cooling to the substrate according to the details of operation, including temperature regulation, discussed immediately below.

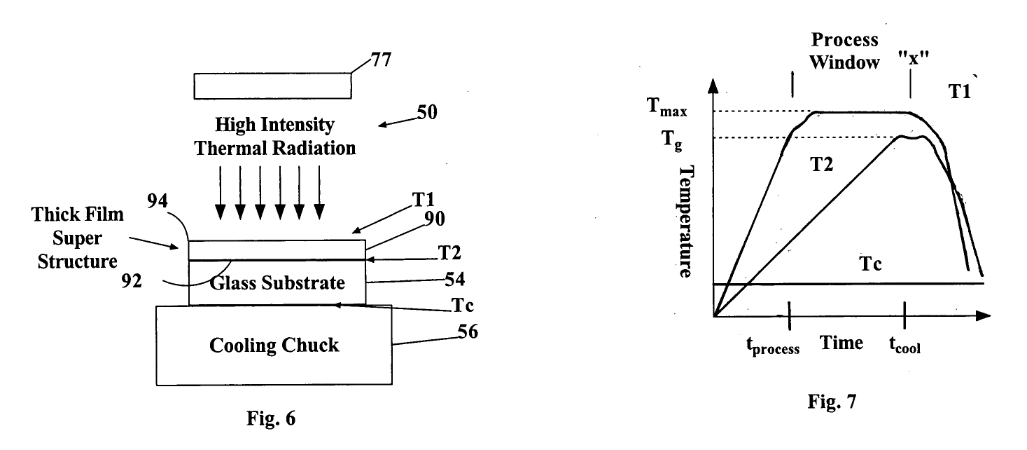

Turning to FIGS. 6 and 7, temperatures associated with the CNT synthesis on a glass substrate 54 and the corresponding operation of system 50 will be discussed in detail. Initially, it is important to note that temperature at preferably three locations (T₁, T₂, T_{C}) is observed with appropriate sensors. On top of substrate 54 is a layer 90 (e.g., a thick film super structure) that may comprise catalyst sites, patterned or not, and electronic components and other structure each having an associated thermal budget (e.g., an electronic component may be rated at 650 degrees Celsius for 10 seconds). A lower surface 92 of layer 90 lies adjacent to the upper surface of substrate 54, while an upper surface 94 of layer 90 faces heat source 77 (of course, heat is transmitted through chamber 52 (FIGS. 4 & 5) not shown in FIG. 6). Top surface 94 defines the location of temperature T₁ which corresponds to the temperature at the reaction site between the carbon molecules and the catalyst to initiate nanotube synthesis.

The temperature T₂ defines the temperature at the interface between surface 92 of layer 90 and the substrate 54. This location must be monitored, either directly or indirectly through computation, to determine whether the rapid heating may compromise the substrate 54. Next, temperature regulated chuck 56 provides backside cooling, for instance, to alter the temperature of the substrate 54. Note that terms such as “backside” that indicate orientation, for example, are used herein for convenience and are not intended to be limiting, unless specifically stated. At the interface of the two, a temperature T_{c} is preferably also monitored, either directly or indirectly through computation, to provide a baseline for operation.

Turning to FIG. 7, the rapid heating, and corresponding temperature regulation are illustrated. In the preferred method, temperature is increased as fast as possible with heat source 77. In response, the temperature at T₁ increases rapidly as optimum CNT growth temperature is approached. Tₘₐₓ defines a maximum temperature for optimum CNT synthesis without compromising the remaining components of the system. Preferably, Tₘₐₓ is greater than or equal to the CNT growth temperature for that application. As T₁ increases, the temperature at the substrate surface increases as well. Because of the increased distance, and the thick film buffer layer 90, however, T₂ does not increase as rapidly.

As the temperature at the surface of substrate 54 approaches the glass transition temperature, the substrate begins to be at risk of being ruined. Therefore, it is preferred to heat as rapidly as possible so the catalyst sites achieve the target temperature for optimum CNT synthesis, while the substrate temperature lags. As shown, there is a process window, the length of which is defined by the point at which the temperature at the catalyst sites T₁ reach the target temperature for CNT synthesis, and the point at which the lagging T₂ reaches the glass transition temperature, T_{g}. At that point (time “t_{cool}”), the preferred embodiment cools the substrate surface to insure the substrate remains in tact. Preferably, the temperature regulated chuck 56 is employed for this purpose. As a result, both T_{1 and T}₂ drop toward the chuck temperature, T_{c}. Importantly, nanotube synthesis, for the applications contemplated by the preferred embodiment no matter what the application parameters, can be completed in a short amount of time once the target temperature is reached. For example, growth of 100 micron nanotubes has been completed in as little as 1 second.

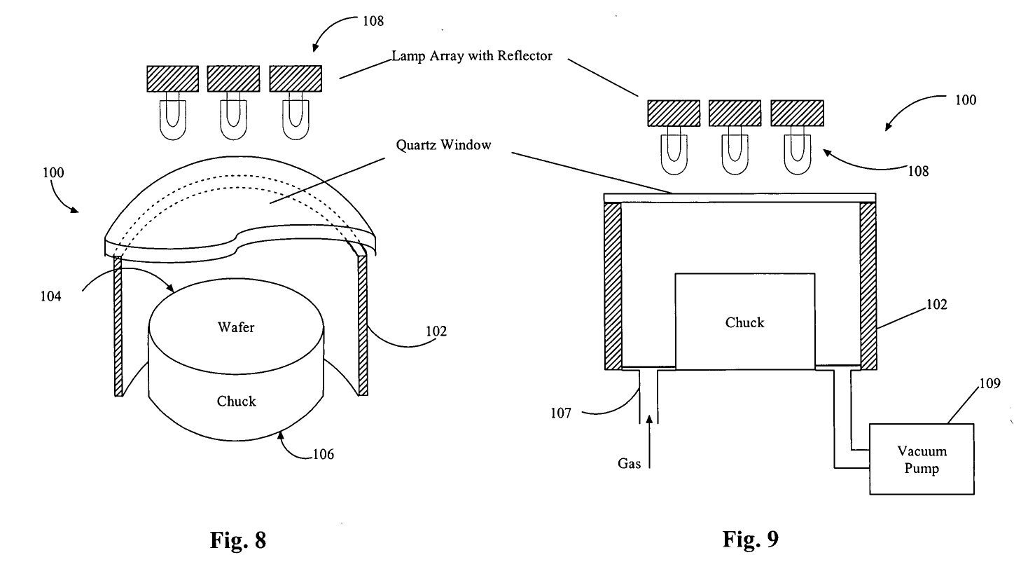

In FIGS. 8 and 9, an alternate embodiment of a system 100, including a chamber 102, is shown. Chamber 102 is preferably quartz and configured to house a round substrate, such as a silicon wafer 104. As with the previous embodiment, wafer 104 is mounted on a temperature regulated chuck 106. A lamp array 108 with a reflector (e.g., 80) is also provided for providing high intensity thermal radiation for optimum CNT synthesis. FIG. 9 illustrates a gas inlet 107 from the bottom of chamber 102, and a vacuum pump 109 is also shown for regulating pressure. It is notable that an array of parameters may be manipulated, in a variety of known combinations too numerous to set forth here, to create ideal conditions for nanotube growth in rapid fashion, whereby the heat energy to which the substrate is exposed is held to a minimum. These parameters include, temperature via heat source (77, 108), pressure via pump (109), gas distribution and mixing via multi-zone shower head (58), and related, again according to specified or selected nanotube growth recipes.

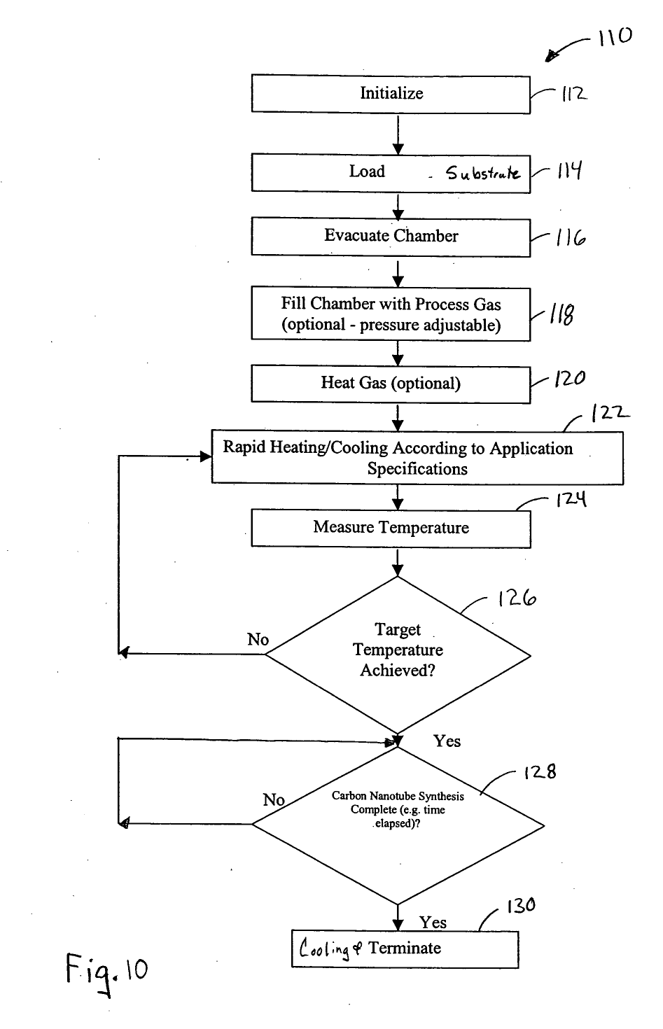

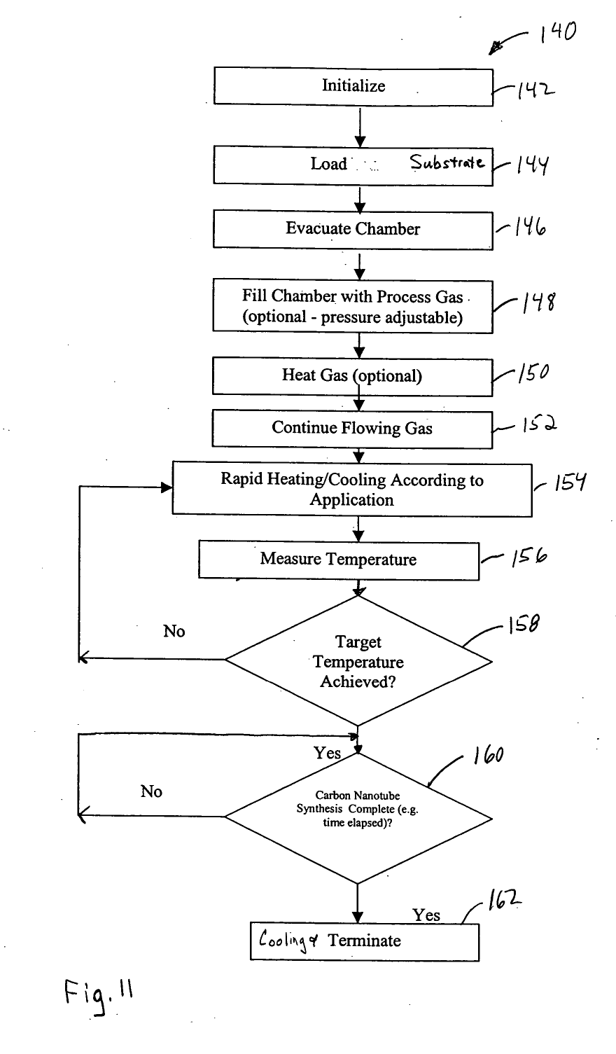

Methods according to the preferred embodiment are shown in FIGS. 10 and 11. In FIG. 10, a method 110 includes a start-up and initialization Block 112. Then, the substrate is loaded in Block 114, and the chamber is evacuated in Block 116. Once the chamber is evacuated, the chamber is filled with process gas(ses) and the pressure may be adjusted according to the application parameters to achieve optimum CNT synthesis conditions in Block 118.

Thereafter in Block 120, the gas may be heated to again optimize conditions. Then, a cycle of rapid heating is initiated in Block 122. This heating is defined by application specifications and should abide by the profile shown in FIG. 7. In Block 124, the temperature is measured, while method 110 determines whether the target temperature has been achieved in Block 126. If not, rapid temperature ramping is continued in Block 122. This process is continued until the target temperature is achieved in Block 126, at which point method 110 determines whether CNT synthesis is complete in Block 128. If not, control may be returned to Block 128, after a delay, until it is determined that CNT synthesis is indeed complete. At that point, a cooling cycle may be initiated (t_{cool} in FIG. 7) using at least one of the heat source and the temperature regulated chuck 56 or 106 as the process is terminated in Block 130.

Turning to FIG. 11, a method 140 similar to method 110 is shown. More particularly, Blocks 142-150 correspond generally to Blocks 112-120 and will not be discussed in detail. In Block 152, method 152 includes the step of continuing to flow gas, as opposed to method 110 where process conditions are established prior to the rapid heating cycle. In this way, optimum CNT synthesis conditions can be achieved by introducing proper distributions of process gas to the chamber. It is known in the art that by manipulating the distribution of process gasses, more uniform synthesis of CNT growth can be achieved. When combined with the temperature regulation of Blocks 154-162 (corresponding to Blocks 122-130 of FIG. 10), optimum conditions for nanotube growth can be achieved in the “process window” defined in FIG. 7.

In an alternative to methods 110 and 140, it is notable that although rapid heating may be performed with the reaction gas environment pre-established (gas distribution, temperature, pressure), the rapid heating may be introduced in the reduction environment where, for example, the iron is converted to iron-oxide. Thereafter, rapid heating is achieved according to FIG. 7, and then the reaction gas is introduced to the chamber under preferably optimum conditions.

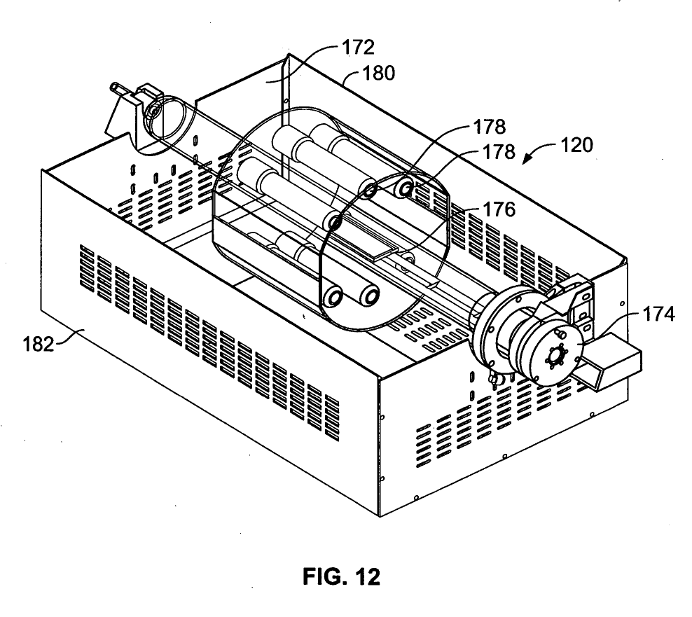

In yet another alternative arrangement, the rapid heating apparatus and method of the preferred embodiment can be employed in an alternately defined configuration as shown in FIG. 12. In this system, an apparatus 170 designed for more small scale substrates includes a chamber 172 and a substrate loading mechanism 174 for supporting a substrate 176 and introducing substrate 176 to chamber 172 under ambient or process (e.g., controlled) conditions. An array of high intensity thermal radiation sources is provided as well as a reflector shield 180 that encompasses a portion of the periphery of the cylindrical chamber 172. Operation is as described above. More details regarding this system can be found in U.S. Ser. Nos. 10/402,454 and 10/402,455, both filed on Mar. 28, 2003, and each of which is expressly incorporated by reference herein.

Although the best mode contemplated by the inventors of carrying out the present invention is disclosed above, practice of the present invention is not limited thereto. It will be manifest that various additions, modifications and rearrangements of the features of the present invention may be made without deviating from the spirit and scope of the underlying inventive concept. The scope of still other changes to the described embodiments that fall within the present invention but that are not specifically discussed above will become apparent from the appended claims.

1. A carbon nanotube fabrication system including a chamber that supports a substrate, the system comprising:
a substrate;
a layer on top of said substrate, said layer having upper and lower generally opposed surfaces and at least one catalyst site for growing a carbon nanotube; and
a high intensity thermal radiation source for heating the chamber, wherein an increase in temperature at said substrate lags a temperature increase at the catalyst site.

2. The system of claim 1, wherein the source includes a reflector.

3. The system of claim 1, further comprising:
a temperature regulation chuck that supports the substrate; and
wherein said chuck cools said substrate so as to prevent damage thereto.

4. The system of claim 3, wherein said layer is a thick film superstructure having upper and lower generally opposed surfaces.

5. The system of claim 4, wherein CNT growth is regulated to occur in a process window substantially defined by a point at which a target temperature for CNT synthesis substantially occurs and a point at which a glass transition temperature of said substrate substantially occurs.

6. The system of claim 1, wherein a CNT synthesis temperature is achieved from an ambient temperature in less than about 1 minute.

7. The system of claim 6, wherein a CNT synthesis temperature is achieved in less than about 30 seconds.

8. A method of producing carbon nanotubes on a substrate, the method comprising the steps of:
heating a chamber to a CNT synthesis temperature faster than heating the chamber to the CNT synthesis temperature in thermal CVD; and
synthesizing the carbon nanotubes in a process window defined by a difference in time between a point at which the CNT temperature is substantially achieved and a point, t_{cool}, at which the temperature at a top surface of the substrate substantially achieves a glass transition temperature.

9. The method of claim 8, further comprising the step of cooling the substrate starting at time t_{cool}.

10. The method of claim 9, wherein said cooling step includes using a temperature regulated chuck that supports said substrate.

11. The method of claim 8, wherein said synthesizing step includes modifying at least one of a pressure in the chamber and a distribution of gas dispensed by a multi-zone shower head.

12. The method of claim 8, wherein a layer is supported by the substrate, the layer having upper and lower generally opposed surfaces separated by a thickness.

13. The method of claim 12, wherein the upper surface includes a plurality of catalyst sites and at least one component having a thermal budget, and wherein said heating step is performed so as to generally not exceed the thermal budget.

14. The method of claim 8, wherein the CNT synthesis temperature is achieved from an ambient temperature in less than about 1 minute.

15. The system of claim 14, wherein the CNT synthesis temperature is achieved in less than about 30 seconds.

16. A carbon nanotube fabrication system including a chamber that supports a substrate, the system comprising:
a high intensity thermal radiation source for heating the chamber;
a temperature regulation chuck that supports the substrate; and
wherein said chuck cools the substrate so as to prevent damage to the substrate during formation of the carbon nanotubes.
